(19) United States
(12) Patent Application Publication
(10) Pub. No.: US 2008/0029884 A1
(43) Pub. Date: Feb. 7, 2008

(54) MULTICHIP DEVICE AND METHOD FOR PRODUCING A MULTICHIP DEVICE

(76) Inventors: Juergen Grafe, Dresden (DE); Kimyung Yoon, Dresden (DE); Peter Poechmueller, Dresden (DE); Andre Hanke, Strausberg (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/462,322

(22) Filed: Aug. 3, 2006

(51) Int. Cl. H01L 23/34

(52) U.S. Cl. 257/723

(57) ABSTRACT

Multichip devices and methods of making the same. In one embodiment, a chip stack is sandwiched between first and second redistribution substrates. The chip stack is electrically connected to contact structures of the first redistribution substrate and the second redistribution substrate.

### BACKGROUND OF THE INVENTION

1. Field of the Invention

The present invention relates to a multichip device including a chip stack and a method for producing such a multichip device.

2. Description of the Related Art

Package stacks wherein a number of separately packaged devices are stacked onto each other to reduce the overall size of a system integrated device are well known. A conventional package comprises a substrate and a die placed on the substrate wherein solder balls which are in electrical contact with the die are arranged surrounding the die area on the substrate. Such a package can be mounted on another one of such packages while the die of the respective other package is arranged in the die area. The overall size is affected as a larger size of the single packages due to the bigger foot print area compared to a normal CSP (chip stack package) is needed. Furthermore, the areas exceeding the die area of the substrate are susceptible to warpage and therefore the total I/0 count is limited.

To improve the package size, a fold stack was developed by using a flex tape. The flex tape connects the solder balls of one package device with the solder balls of another package device which are stacked onto each other wherein the flex tape is folded around the package devices which requires additional assembly processes and increases the size of the package stack due to the dimensions of the flex tape.

An alternative possibility is to place an interposer on the active die of one package device to allow the assembly of another package on it. The interposer, however, has to be connected to the package substrate via bond wires and requires a window molding process, i.e. requires a window such that the contact pads on the interposer can be externally contacted.

There is a need of easy to use and easy to produce package stack devices to provide multi-chip devices having a high performance system integration.

### SUMMARY OF THE INVENTION

One or more advantages of the present invention are described below with regard to different aspects and embodiments of the present invention.

According to a first aspect, a multichip device is provided which comprises a first and a second redistribution substrate each having one or more of first contact structures on a first surface and one or more of second contact structures on a second surface wherein the first and the second contact structures are electrically interconnected in a predetermined manner. Furthermore, a chip stack having a plurality of stacked chips is provided wherein a first outer chip and a second outer chip are arranged to form opposing outer surfaces of the chip stack. The first outer chip is electrically connected to the second contact structure of the first redistribution substrate and the second outer chip is electrically connected to the second contact structure of the second redistribution substrate.

At least one of the first and second outer chips of the chip stack may have on its surface forming one of the outer surfaces of the chip stack one or more contact elevations which are in electrical contact to the respective second contact structures of at least one of the first and second redistribution substrates.

Additionally, at least one of the chips of the chip stack has one or more third contact structures on a surface portion uncovered by an adjacent one of the chips of this chip stack wherein the third contact structures are electrically connected with the second contact structures of at least one of the first and the second redistribution substrates by means of one or more respective bond wires.

According to a further aspect, a multichip device is provided which comprises a first and a second redistribution substrate each having one or more of first contact structures on a first surface and one or more of second contact structures on a second surface wherein the first and the second contact structures are electrically interconnected in a predetermined manner. The multichip device further comprises a chip stack sandwiched between the first and second redistribution substrates and having a plurality of stack chips wherein the first outer chip and a second outer chip are arranged to form opposing outer surfaces of the chip stack wherein the second surfaces of the first and the second redistribution substrates opposing each other. The first outer chip is electrically connected to the second contact structures of the first redistribution substrate and the second outer chip is electrically connected to the second contact structure of the second redistribution substrate. The one or more first contact structures on the first surface of one of the first and the second redistribution substrates comprise one or more outer contact elevations wherein the first surface of the respective other of the first and second redistribution substrate are formed as contact pads.

According to a further aspect, a multichip device is provided. The multichip device comprises a first and a second redistribution substrate each having one or more of first contact structures on a first surface and one or more of second contact structures on a second surface wherein the first and the second contact structures are electrically interconnected in a predetermined manner. A chip stack is sandwiched before the first and the second redistribution substrates wherein the second surfaces of the first and the second redistribution substrates opposing each other wherein the chip stack having a plurality of stacked chips wherein a first outer chip and a second outer chip are arranged to form opposing outer surfaces of the chip stack. The first outer chip is electrically connected to the second contact structure of the first redistribution substrate and the second outer chip is electrically connected to the second contact structure of the second redistribution substrate. The one or more first contact structures on at least one of the first surfaces of the first and the second redistribution substrates at least partially comprise one or more outer contact elevations wherein the respective other contact structure a formed as contact pads.

According to a further aspect, a multichip device is provided. The multichip device comprises a first and a second redistribution substrate each having one or more first contact structures on a first surface and ore or more second contact structures on a second surface wherein the first and the second contact structures are interconnected in a predetermined manner. A chip stack is sandwiched between the first and the second redistribution substrates and has a plurality of chips wherein a first outer chip and a second outer chip are arranged to form opposing outer surfaces of the chip stack. The first outer chip is attached on the first redistribution substrate and the second outer chip is attached on the second redistribution substrate wherein one of the first and the second outer chips has on its respective surface forming the outer surface of the chip stack one or more contact elevations which are in electrical contact to one or more second contact structures of the first redistribution substrate. One of the chips of the chip stack has one or more third contact structures on a surface portion uncovered by an adjacent one of the chips of the chip stack wherein the third contact structures are electrically contacted with the second contact structures of the second redistribution substrate by means of a bond wire.

According to a further aspect, a multichip device is provided comprising a first and a second redistribution substrate each having a plurality of first contact structures on a first surface and a plurality of second contact structures on a second surface wherein the first and the second contact structures are interconnected in a predetermined manner. A plurality of chip stacks are sandwiched between the first and the second redistribution substrates, each having a plurality of chips. A first outer chip and a second outer chip are arranged to form opposing outer surfaces of the respective chip stack. First one of the plurality of the chip stacks is arranged so that the first outer chip is arranged on the first redistribution substrate wherein the first outer chip has on its surface forming an outer surface of the chip stack one or more contact elevations which are in electrical contact to the respective second contact structures of the first redistribution substrate. A second one of the plurality of the chip stack is arranged so that the first outer chip is attached on the second redistribution substrate wherein the first outer chip has on its surface forming an outer surface of the chip stack one or more contact elevations which are in electrical contact to the respective second contact structures of the second redistribution substrate.

According to a further aspect, an electronic device having a first and a second printed circuit board is provided wherein one or more multichip devices of the above mentioned type are sandwiched between the first and the second printed circuit boards such that each of the multichip devices is electrically connected to interconnection structures of at least one of the first and the second printed circuit board.

According to further aspects of the present invention, package stacks having a plurality of stack multichip devices of one of the above mentioned type are provided wherein the first contact structures of the first redistribution substrate of a first one of the multichip devices are brought into contact with the second contact structures of the second redistribution substrate of a second one of the multichip devices.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a multichip device according to an embodiment of the present invention;

FIG. 2 shows a process state of an assembly process to produce a multichip device according to an embodiment of the present invention;

FIG. 3 shows a package stack having a plurality of multichip devices stacked on each other according to a further embodiment of the present invention;

FIGS. 4A and 4B show a further embodiment of a multichip device and the process to produce such a multichip device;

FIG. 5 shows an electronic device having a plurality of multichip devices according to a further embodiment of the present invention; and

FIG. 6 shows a multichip device having edge contacts according to a further embodiment of the present invention.

### DETAILED DESCRIPTION OF THE PREFERRED EMBODIMENT

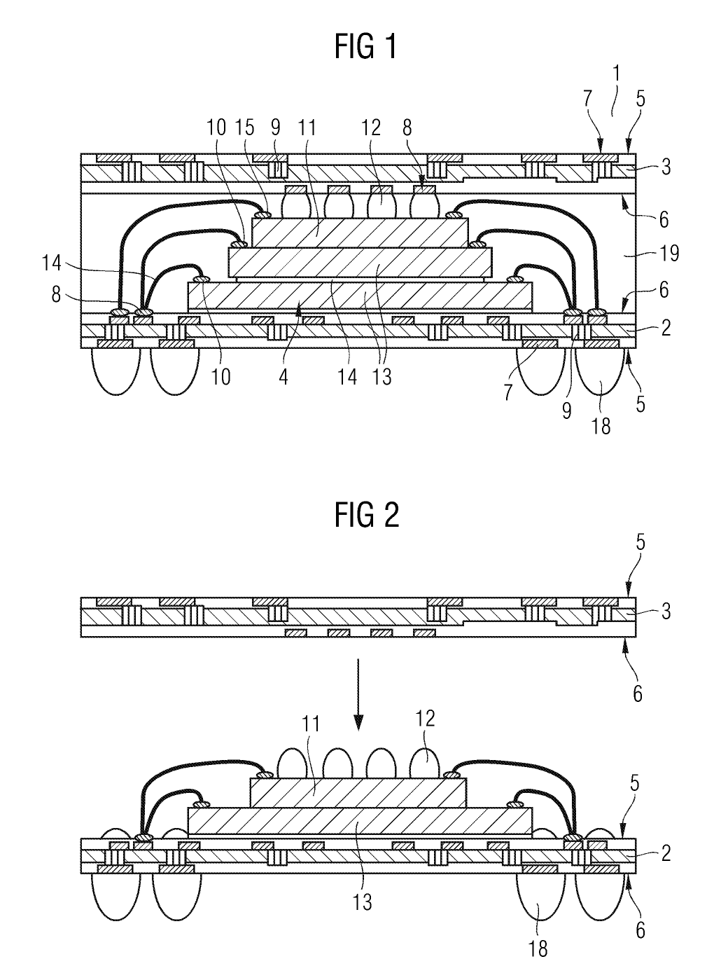

In FIG. 1, a multichip device 1 of a first embodiment is depicted. The multichip device 1 comprises a first redistribution substrate 2 and a second redistribution substrate 3 in between which a chip stack 4 is arranged. Each of the redistribution substrates 2, 3 is preferably made of a nonconductive resin as commonly used for printed circuit boards (PCB) and has a first surface 5 and a second surface 6 on which first contact structures 7 and second contact structures 8 are formed, respectively. The first and the second redistribution substrates 2, 3 are arranged to sandwich the chip stack 4 such that the first and the second redistribution substrates 2, 3 extend substantially in parallel, wherein its second surfaces 6 opposing each other. Each of the redistribution substrates 2, 3 may comprise a plurality of redistribution structures 9 allowing association with one or more of the first contact structures 7 on the first surface of each of the redistribution substrates 2, 3 to one or more second contact structures 8 on a second surface of the respective redistribution substrate 2, 3 to provide an electrical interconnection, respectively.

The chip stack 4 may comprise chips 13 having bond pads 10 on it and may comprise a flip-chip device 11 as an outer die of the chip stack 4. The flip chip device 11 has contact elevations 12 which are arranged to provide a contact with second contact structures 8 on the second surface 6 of one of the redistribution substrate 3. The second contact structures 8 of the respective redistribution substrate 3 are preferably formed as contact pads which are in an arrangement corresponding to the arrangement of the contact elevations 12 of the flip-chip device 11. The further chips 13 are stacked onto each other on the second surface 6 of the first redistribution substrate 2 such that their bond pads 10 remain uncovered and substantially are directed in the same direction as the second surface 6 of the first redistribution substrate 2. Bond wires 14 are provided to connect the uncovered bond pads 10 of the respective chips 13 with the respective second contact structures 8 on the second surface 6 of the first redistribution substrate 2.

Between the chips 13 an interposer 14 may be provided if more vertical space for performing the bonding is necessary and which can also function as an adhesive layer to mount the chips 13 together.

Besides the contact elevation 12 of the flip-chip device 11 also further contact structures 15 may be provided on the flip-chip device 11 which are directed in the same direction as the bond pads 10 of the chips 13 and which may be bonded by a bonding process with a respective second contact structure 8 on the second surface 6 of the first redistribution substrate 2.

The multichip device 1 therefore provides contact structures 18 on both surfaces represented by the first surfaces 5 of the first and second redistribution substrates 2, 3 such that the I/O counts of the multichip device 1 may be increased and such that multichip devices 1 can be stacked together without the provision of any further measures such as an interposer, a flex interconnection and the like.

The space in between the first and the second redistribution substrates 2, 3 may be filled with a molding material 19 to encapsulate the chip stack and to further improve the mechanical stability of the multichip device 1.

In FIG. 2, an assembly process of such a multichip device 1 is depicted. The assembly process provides to attach a chip stack onto a first redistribution substrate 2 having a flip-chip device 11 as the most upper chip having solder balls 12 directed in the same direction as the second surface 6 of the first redistribution substrate 2, i.e. towards the second redistribution substrate 3 to be mounted. The second redistribution substrate 3 is attached onto the solder balls 12 of the flip-chip device 11 such that its second contact structures 8 (contact pads) come in contact with the solder balls 12 and which are connected to each other by means of solder bridge or the like formed by a reflow process. The reflow of the solder balls provide an electrical connection as well as a mechanical fixation of the second redistribution substrate 3 on the chip stack 4.

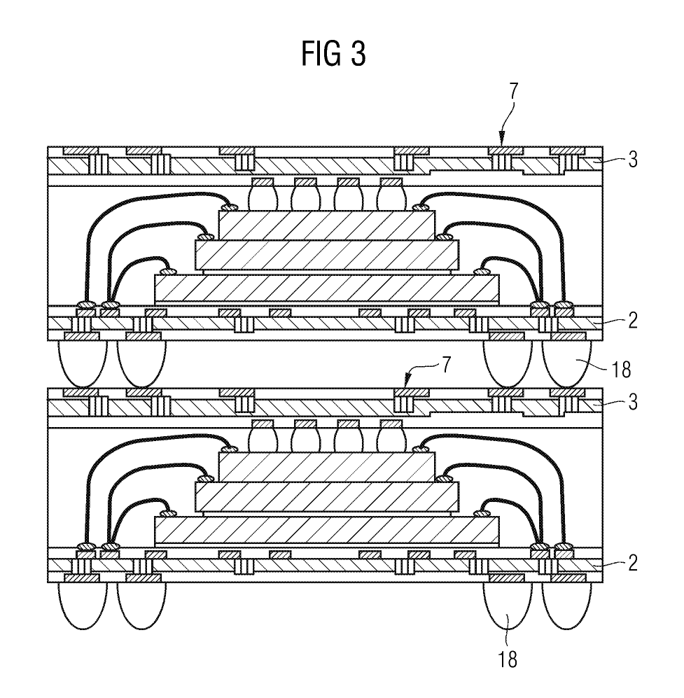

As shown in FIG. 3, by the provision of contact elevations 18 in form of solder balls on the first surface of the redistribution substrate 2 and respective contact pads 7 on the first surface of the second redistribution substrate 3, the multichip device 1 can be provided in such a manner that a plurality of multichip devices 1 can be stacked onto each other by arranging the contact elevations of the first redistribution substrate of a first of the multichip devices to the contact pads of the second redistribution substrate 3 of a second one of the multichip devices.

A large number of variations of the embodiments described above are possible without leaving the scope of the present invention. With regard to this, it is further possible to provide in the chip stack 4 two flip-chip devices 11 and both surfaces of the chip stack 4 such as to connect each of the contact elevations 12 of the respective flip-chip device 11 with one of the redistribution substrates 2, 3. One or more further chips 13 can be arranged which are connected to one or both of the redistribution substrates 2, 3 by means of respective bond wires 8. In contrast to the arrangement of the contact elevations 18 on the first surface 5 of the first redistribution substrate 2 and the contact pads 7 on the first surface 5 of the second redistribution substrate 3, it is further possible that both first surfaces 7 of the redistribution substrates 2, 3 are provided with contact elevations 18, and it is even possible that contact pads as well as contact elevations are provided on the same surface 5 of the respective redistribution substrate 2, 3. In this case, the arrangement of contact elevations 18 and contact pads 7 of the first redistribution substrate 2 should be adapted to a respective arrangement of contact pads 7 and contact elevations 18 of a surface to which the respective surface is to be electrically connected such that a pair of a contact elevation and a contact pad are associated to each other, respectively.

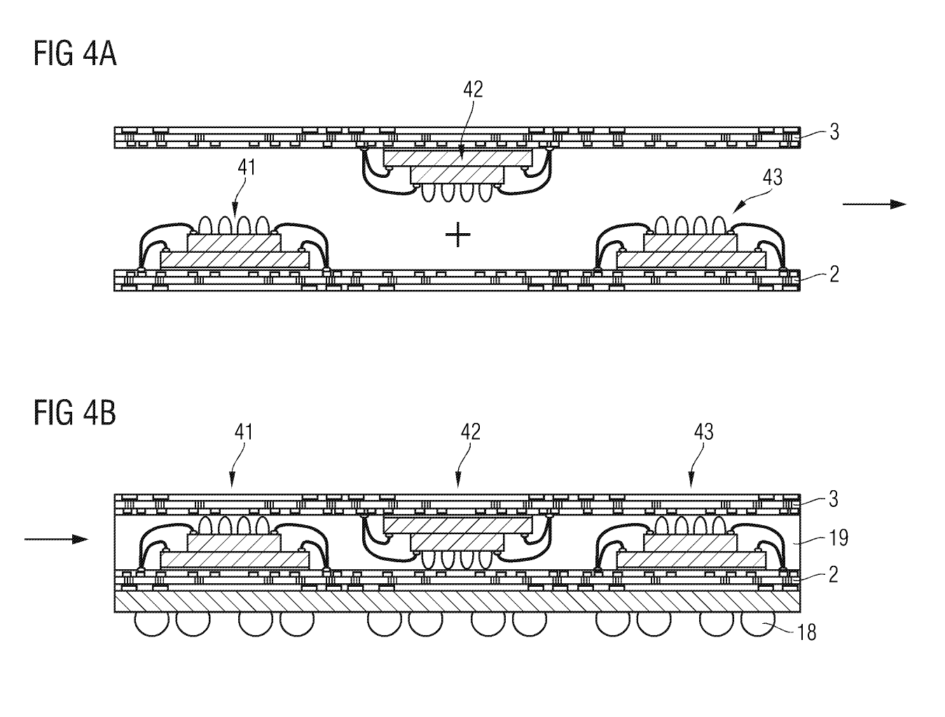

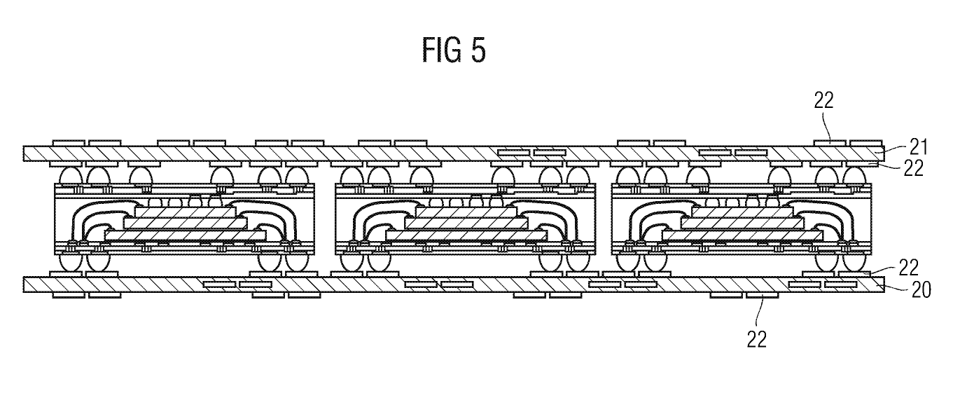

In FIGS. 4A and 4B, another embodiment of the present invention is depicted wherein a plurality of chip stacks 41, 42 ,43 is arranged between a first and a second redistribution substrates 2, 3. The arrangement of a chip stack 4 as known from the embodiment of FIG. 1 may be performed such, that a first one of the chip stacks 41 having one or more chips 13 and a respective flip-chip device 11 arranged on top of the first chip stack 41 is attached on the first redistribution substrate 2 such that the contact elevations 12 on the respective flip-chip device 11 are directed in the same direction as the second surface 8 of the first redistribution substrate 2 and that a second one of the chip stacks 42 is arranged on the second redistribution substrate 3 such that the contact elevations 12 of the respective flip-chip device 11 are directed in the same direction as the second surface 6 of the second redistribution substrate 3 such that the chip stacks 41, 42, 43 each having one flip-chip device 11 being directed into different directions, respectively. In other words, while the first chip stack 41 having a flip-chip device 11 which is directed (with its contact elevations/solder ball side) in the first direction, the second chip stack 42 is arranged top side down with respect to the first chip stack 41.

In any case, as shown in FIG. 4B, the electrical connection between the first and the second redistribution substrates 2, 3 is performed by a reflow process. Thereby, contact elevations of the respective flip-chip devices 11 of the chip stacks 41, 42, 43 are brought into contact with respective contact pads on the second surface 6 of the respective other redistribution substrate 2, 3 and a common reflow process is performed such that the solder balls 12 of the flip-chip devices 11 melt and an electrical connection between the solder balls and the contact pads is achieved. Such an arrangement allows a denser packaging of chip stacks 41, 42, 43 as the stacked bare dies can be arranged close to each other without being packaged before.

In FIG. 5, a further embodiment of the present invention is shown wherein multichip devices 1 are provided with contact elevations in form of solder balls 18 on each of the first surfaces 5 of both redistribution substrates 2, 3. A plurality of such multichip devices 1 is arranged between a first and a second printed circuit board 20, 21 such that each of the plurality of multichip devices 1 is electrically contacted by the first and the second printed circuit board 20, 21. Thereby, complex electronic systems can be assembled. At least one of the printed circuit boards has contact areas 22 on both sides, which might be interconnected by means of suitable redistribution structures. The contact elevations 18 on the first surfaces 5 of the redistribution substrates 2, 3 may be connected with the respective contact areas 22 by means of a conductive adhesive, solder paste and the like.

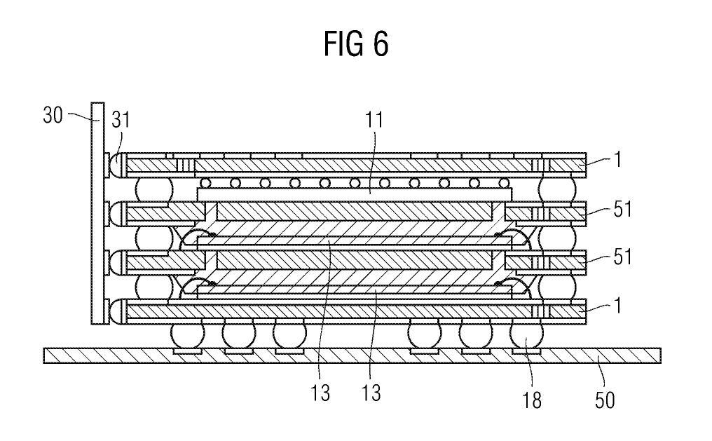

As shown in FIG. 6, it is also possible to provide a chip stack 4 on a PCB substrate 50, wherein the chips of the chip stack 4 further have edge contacts 31 on at least one of its redistribution substrates 2, 3 such that the multichip device 1 or a plurality of stacked multichip devices 1 can be contacted via the edge contacts 31 on the edges of at least the redistribution substrates 2, 3 e.g. by means of a flexible interconnection element 30, which provides an optical and/or electrical connection. The interconnection between the flexible interconnection element 30 and the edge contacts can be provided by a conductive adhesive solder paste, a mechanical connection, a clamping connection and the like.

The chip stack can be further provided with intermediate substrates 51 which carry at least one chip and which are stacked with further intermediate substrates 51 and/or further intermediates substrates 51 including one or more and bare dies. The intermediate substrates 51 also have one or more edge contacts 31. The chips 13 stacked with the intermediate substrates 51 are banded to the respective adjacent intermediate substrate 51 via bond wires, for example. Between adjacent redistribution/intermediate substrates 2, 3, 51, solder bridges can be provided to electrically interconnect the respective substrates 2, 3, 51 directly.

While the foregoing is directed to embodiments of the present invention, other and further embodiments of the invention may be devised without departing from the basic scope thereof, and the scope thereof is determined by the claims that follow.

What is claimed is:

1. A multichip device, comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates and having a plurality of stacked chips, wherein a first outer chip and a second outer chip are arranged to form opposing outer surfaces of the chip stack;
wherein the first outer chip is electrically connected to the second contact structure of the first redistribution substrate and the second outer chip is electrically connected to the second contact structure of the second redistribution substrate.

2. The multichip device according to claim 1, wherein one or more contact elevations are formed on at least one of the opposing outer surfaces of the chip stack, the contact elevations being in electrical contact to the respective second contact structures of at least one of the first and the second redistribution substrates.

3. The multichip device according to claim 2, wherein at least one of the outer chips of the chip stack is a Flipchip device having solder balls as the contact elevations.

4. The multichip device according to claim 1, wherein at least one of the chips of the chip stack has one or more third contact structures on a surface portion uncovered by an adjacent one of the chips of the chip stack and wherein the third contact structures are electrically connected with the second contact structures of at least one of the first and the second redistribution substrates by one or more respective bondwires.

5. The multichip device according to claim 1,
wherein the one or more contact elevations are disposed on one of the outer surfaces of the chip stack defined by the first outer chip, the contact elevations being in electrical contact to the respective second contact structures of the first redistribution substrates, and
wherein at least one of the chips of the chip stack has one or more third contact structures on a surface portion uncovered by an adjacent one of the chips of the chip stack wherein the third contact structures are electrically connected with the second contact structures of the second redistribution substrates by one or more bondwires.

6. The multichip device according to claim 1, further comprising an interposer disposed between at least two of the plurality of chips of the chip stack.

7. The multichip device according to claim 1, wherein the second surfaces of the first and the second redistribution substrates are in opposing facing relation to each other, wherein the one or more of the first contact structures comprise one or more outer contact elevations.

8. The multichip device according to claim 1, wherein the first and the second redistribution substrates each comprise a redistribution layer to provide an interconnection between the respective first and second contact structures.

9. A multichip device, comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates and having a plurality of stacked chips wherein a first outer chip and a second outer chip are arranged to form opposing outer surfaces of the chip stack, wherein the second surfaces of the first and the second redistribution substrates are in opposing facing relation;
wherein the first outer chip is electrically connected to the second contact structure of the first redistribution substrate and the second outer chip is electrically connected to the second contact structure of the second redistribution substrate; and
wherein the one or more first contact structures on the first surface of one of the first and second redistribution substrates comprise one or more outer contact elevations, and wherein the one or more first contact structures on the first surface of the respective other of the first and second redistribution substrates are contact pads.

10. The multichip device according to claim 9, wherein at least one of the outer chips of the chip stack is a Flipchip device having solder balls as the contact elevations.

11. The multichip device according to claim 9, wherein the first and the second redistribution substrates each comprise a redistribution layer disposed between the respective first and second contact structures and configured to provide an electrical interconnection between the respective first and second contact structures.

12. A multichip device, comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates, wherein the second surfaces of the first and the second redistribution substrates are in opposing facing relation, wherein the chip stack comprises a plurality of stacked chips, wherein a first outer chip and a second outer chip are arranged to form opposing outer surfaces of the chip stack;
wherein the first outer chip is electrically connected to the second contact structure of the first redistribution substrate and the second outer chip is electrically connected to the second contact structure of the second redistribution substrate; and
wherein the one or more first contact structures on at least one of the first surfaces of the first and second redistribution substrates at least partially comprise one or more outer contact elevations and the respective other contact structures are formed as contact pads.

13. The multichip device according to claim 12, wherein at least one of the outer chips of the chip stack is a Flipchip device having solder balls as the contact elevations.

14. The multichip device according to claim 12, wherein the first and the second redistribution substrates each comprise a redistribution layer disposed between the respective first and second contact structures and configured to provide an electrical interconnection between the respective first and second contact structures.

15. A multichip device, comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates and having a plurality of chips wherein a first outer chip and a second outer chip are arranged to form opposing outer surfaces of the chip stack;
wherein the first outer chip is attached to the first redistribution substrate and the second outer chip is attached to the second redistribution substrate;
wherein one of the first and the second outer chips has on its respective surface forming the outer surface of the chip stack one or more contact elevations which are in electrical contact with the one or more second contact structures of the first redistribution substrate; and
wherein one of the chips of the chip stack has one or more third contact structures on a surface portion uncovered by an adjacent one of the chips of the chip stack, wherein the third contact structures are electrically contacted with the second contact structures of the second redistribution substrate by a bondwire.

16. A multichip device, comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a plurality of chip stacks each sandwiched between the first and second redistribution substrates and each having a plurality of chips including a first outer chip and a second outer chip being arranged to form opposing outer surfaces of the respective chip stack;
wherein a first one of the plurality of the chip stacks is arranged so that the respective first outer chip is attached to the first redistribution substrate, and wherein the first outer chip has on its surface forming an outer surface of the chip stack one or more contact elevations which are in electrical contact to the respective second contact structures of the first redistribution substrate; and
wherein a second one of the plurality of the chip stacks is arranged so that the respective first outer chip is attached to the second redistribution substrate wherein the first outer chip has on its surface forming an outer surface of the chip stack one or more contact elevations which are in electrical contact to the respective second contact structures of the second redistribution substrate.

17. The multichip device according to claim 9, wherein the second outer chip of the first chip stack has one or more third contact structures which are connected to the second contact structures of the second redistribution substrate by one or more first bondwires, and
wherein the second outer chip of the second chip stack has third contact structures which are connected to the respective second contact structures of the first redistribution substrate by one or more second bondwires.

18. An electronic device, comprising:
a first and a second printed circuit board; and
a multichip device sandwiched between the first and the second printed circuit boards and electrically connected to interconnection structures of at least one of the first and the second printed circuit board; wherein the multichip device comprises:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates and having a plurality of stacked chips, wherein a first outer chip and a second outer chip are arranged to form opposing outer surfaces of the chip stack;
wherein the first outer chip is electrically connected to the second contact structure of the first redistribution substrate and the second outer chip is electrically connected to the second contact structure of the second redistribution substrate.

19. A package stack, comprising:
a plurality of stacked multichip devices, each multichip device comprising:
a first and a second redistribution substrate each having a respective first and second surface on opposite sides of the respective substrate and each having one or more of first contact structures on the respective first surface and one or more of second contact structures on the respective second surface, wherein the first and the second contact structures are electrically interconnected; and
a chip stack sandwiched between the first and second redistribution substrates and having a plurality of stacked chips, wherein a first outer chip and a second outer chip are arranged to form opposing outer surfaces of the chip stack;
wherein the first outer chip is electrically connected to the second contact structure of the first redistribution substrate and the second outer chip is electrically connected to the second contact structure of the second redistribution substrate; and
wherein the first contact structures of the first redistribution substrate of a first one of the multichip devices are brought into contact with the second contact structures of the second redistribution substrate of a second one of the multichip devices.
